(19) United States
(12) Patent Application Publication
(10) Pub. No.: US 2026/0190708 A1
(43) Pub. Date: Jul. 2, 2026

(54) ELECTRONIC APPARATUS

(71) Applicant: Samsung Display Co., Ltd., Yongin-si (KR)

(72) Inventors: WONWOO CHOI, Yongin-si (KR); JONGSEOK KIM, Yongin-si (KR); KIYOUNG KIM, Yongin-si (KR); DONGLIM KIM, Yongin-si (KR); HEEJUNG YOON, Yongin-si (KR); SEONGJUN LEE, Yongin-si (KR)

(21) Appl. No.: 19/386,909

(22) Filed: Nov. 12, 2025

(30) Foreign Application Priority Data
Dec. 30, 2024 (KR) 10-2024-0201088

(51) Int. Cl. H10K 59/131; G06F 3/041; H10K 59/40

(52) U.S. Cl. CPC H10K 59/131; H10K 59/40; G06F 3/0412

(57) ABSTRACT

An electronic apparatus includes a display panel having a display region including a first region and a second region, and an input sensor layer including first sensing electrodes extending in a first direction, second sensing electrodes extending in a second direction, and a conductive pattern in the first region. The display panel includes first emission parts including a longer side extending in a first diagonal direction tilted with respect to the first and second directions, and a shorter side extending in a second diagonal direction, second emission parts including sides having an equal length, and transmissive parts in the first region and spaced apart from the first and second emission parts. The conductive pattern includes first patterns extending in the first diagonal direction and second patterns extending in the second diagonal direction, and one of the first patterns is adjacent to a longer side that faces the transmissive part.

### CROSS-REFERENCE TO RELATED APPLICATION

The present application claims priority to and the benefit of Korean Patent Application No. 10-2024-0201088 filed on Dec. 30, 2024, in the Korean Intellectual Property Office, the entire disclosure of which is incorporated herein by reference.

### BACKGROUND

Aspects of some embodiments of the present disclosure described herein relate to an electronic apparatus.

An electronic apparatus may be activated in response to an electrical signal and may include various electronic parts such as a display unit or a sensing unit to sense an external input. Such electronic parts may be electrically connected to each other through signal lines arranged variously.

An electronic module may include a camera, an infrared sensing sensor, or a proximity sensor, and may be arranged under the display module. The display module may include an active region for displaying images and a peripheral region adjacent to the active region. The electronic module may be mainly under the peripheral region.

The display module may include a light emitting element to generate an image, and the input sensor may include a sensing electrode to sense the external input. The sensing electrode is in the active region, and the input sensor is designed to provide uniform sensitivity with respect to the entire surface of the active region.

The above information disclosed in this Background section is only for enhancement of understanding of the background and therefore the information discussed in this Background section does not necessarily constitute prior art.

### SUMMARY

Aspects of some embodiments of the present disclosure described herein relate to an electronic apparatus and for example, to an electronic apparatus to sense an external input. Aspects of some embodiments of the present disclosure include an electronic apparatus capable of relatively improving transmittance in a sensing region, and of constantly providing a brightness value with respect to the entire surface of the display region.

According to some embodiments, an electronic apparatus includes a display panel divided into a display region including a first region and a second region having a transmittance lower than a transmittance of the first region, and a non-display region adjacent to the display region, when viewed in a plan view, and an input sensor layer on the display panel, and including a plurality of first sensing electrodes in the display region and extending in a first direction, a plurality of second sensing electrodes in the display region and extending in a second direction crossing the first direction, and a conductive pattern in the first region. According to some embodiments, the display panel includes first emission parts, each first emission part including a longer side extending in a first diagonal direction tilted with respect to the first direction and the second direction, and a shorter side extending in a second diagonal direction crossing the first diagonal direction, second emission parts, each second emission part having sides having an equal length, and a plurality of transmissive parts in the first region and spaced apart from the first and second emission parts. According to some embodiments, the conductive pattern includes a plurality of first patterns extending in the first diagonal direction and a plurality of second patterns extending in the second diagonal direction. According to some embodiments, at least one of the first patterns is adjacent to a longer side, which faces the transmissive part, of the longer sides.

According to some embodiments, some of the first patterns may have a length equal to a length of the longer side.

According to some embodiments, the conductive pattern may be electrically connected to the first sensing electrodes and electrically insulated from the second sensing electrodes.

According to some embodiments, the conductive pattern may be electrically insulated from the first and second sensing electrodes.

According to some embodiments, first patterns, which have the length equal to the length of the longer side, of the first patterns may be adjacent to longer sides facing the transmissive part.

According to some embodiments, the first patterns and the second patterns may be adjacent to only any one side of the sides of the second emission parts.

According to some embodiments, the first patterns and the second patterns may be adjacent to one side of the second emission parts and a side opposite to the one side.

According to some embodiments, an electronic apparatus may further include third emission parts including sides having an equal length as a second length, the second emission parts may be at the longer sides of the first emission parts, and the third emission parts may be at the shorter sides of the first emission parts.

According to some embodiments, the conductive pattern may further include third patterns overlapped with the plurality of transmissive parts.

According to some embodiments, the third patterns may be in a layer different from a layer for the first patterns and the second patterns.

According to some embodiments, the third patterns may include a material different from a material for the first patterns and the second patterns.

According to some embodiments, the third patterns may include a transparent conductive oxide.

According to some embodiments, the third patterns may be electrically connected to the first sensing electrodes or the second sensing electrodes.

According to some embodiments, the first region may have a circle shape when viewed in a plan view.

According to some embodiments, the first region may be overlapped with any one of the first and second sensing electrodes, when viewed in a plan view.

According to some embodiments, the first region may have an elliptical shape, when viewed in a plan view.

According to some embodiments, the first region may be overlapped with at least a portion of the first sensing electrodes adjacent to the first region and at least a portion of the second sensing electrodes adjacent to the first region, when viewed in a plan view.

According to some embodiments, the conductive pattern may be electrically connected to the first and second sensing electrodes.

According to some embodiments, an electronic apparatus includes a camera module, a display panel divided into a display region including a first region overlapped with the camera module and a second region having a transmittance lower than a transmittance of the first region, and a non-display region adjacent to the display region, when viewed in a plan view, and an input sensor layer on the display panel, and including a plurality of first sensing electrodes in the display region and extending in a first direction, a plurality of second sensing electrodes in the display region and extending in a second direction crossing the first direction, and a conductive pattern in the first region. According to some embodiments, the display panel includes first emission parts, each first emission part including a longer side extending in a first diagonal direction tilted with respect to the first direction and the second direction, and a shorter side extending in a second diagonal direction crossing the first diagonal direction, second emission parts, each second emission part having sides having an equal length, and a plurality of transmissive parts in the first region and spaced apart from the first and second emission parts. According to some embodiments, the conductive pattern includes a plurality of first patterns extending in the first diagonal direction and a plurality of second patterns extending in the second diagonal direction. According to some embodiments, at least one of the first patterns is adjacent to the longer side among the longer sides that faces the transmissive part.

According to some embodiments, some of the first patterns may have a length equal to a length of the longer side, and first patterns, which have the length equal to the length of the longer side, of the first patterns may be adjacent to longer sides facing the transmissive part.

### BRIEF DESCRIPTION OF THE FIGURES

The above and other aspects and characteristics of embodiments according to the present disclosure will become more apparent by describing in more detail aspects of some embodiments thereof with reference to the accompanying drawings.

FIG. 1 is a block diagram illustrating an electronic apparatus according to some embodiments.

FIG. 2 is a view schematically illustrating an electronic apparatus according to some embodiments.

FIG. 3 is a perspective view illustrating an electronic apparatus according to some embodiments of the present disclosure.

FIG. 4 is an exploded perspective view illustrating an electronic apparatus according to some embodiments of the present disclosure.

FIG. 5 is a cross-sectional view illustrating an electronic apparatus illustrated in FIG. 3.

FIG. 6 is a cross-sectional view illustrating a display panel illustrated in FIG. 3.

FIG. 7 is a plan view illustrating a display panel according to some embodiments of the present disclosure.

FIG. 8 is a plan view illustrating an input sensor layer according to some embodiments of the present disclosure.

FIG. 9 is a cross-sectional view illustrating an electronic panel according to some embodiments of the present disclosure.

FIG. 10 is an enlarged plan view illustrating a partial region of an electronic apparatus.

FIG. 11A is a cross-sectional view illustrating an electronic apparatus according to some embodiments of the present disclosure.

FIG. 11B is a cross-sectional view illustrating an electronic apparatus according to some embodiments of the present disclosure.

FIG. 12 is an enlarged plan view illustrating a partial region of an electronic apparatus.

FIG. 13 is an enlarged plan view illustrating a partial region of an electronic apparatus.

FIGS. 14 and 15 are enlarged plan views of a region AA′ of FIG. 8.

FIG. 16 is an enlarged plan view of a region AA′ of FIG. 8.

### DETAILED DESCRIPTION

In this specification, the expression that a first component (or region, layer, or part) is “on”, “connected to”, or “coupled to” a second component refers to that the first component is directly on, connected to, or coupled to the second component or refers to that a third component is interposed therebetween.

The same reference numeral will be assigned to the same component. In addition, in drawings, thicknesses, proportions, and dimensions of components may be exaggerated to describe the technical features effectively. The term “and/or” includes any and all combinations of one or more of associated components

Although the terms “first”, or “second” may be used to describe various components, the components should not be construed as being limited by the terms. The terms are only used to distinguish one component from another component. For example, without departing from the scope and spirit of the present disclosure, a first component may be referred to as a second component, and similarly, the second component may be referred to as the first component. The singular forms are intended to include the plural forms unless the context clearly indicates otherwise.

In addition, the terms “under”, “at a lower portion”, “above”, “an upper portion” are used to describe the relationship between components illustrated in drawings. The terms are relative and will be described with reference to a direction indicated in the drawing.

It will be further understood that the terms “comprise,” “include,” or “including,” or “have” or “having” specify the presence of stated features, numbers, steps, operations, components, parts, or the combination thereof, but do not preclude the presence or addition of one or more other features, numbers, steps, operations, components, components, and/or the combination thereof.

Unless defined otherwise, all terms (including technical terms and scientific terms) used in the specification have the same meaning as commonly understood by one skilled in the art to which the present disclosure belongs. Furthermore, terms such as terms defined in the dictionaries commonly used should be interpreted as having a meaning consistent with the meaning in the context of the related technology, and should not be interpreted in ideal or overly formal meanings unless explicitly defined herein.

Hereinafter, aspects of some embodiments of the present disclosure will be described in more detail with reference to drawings.

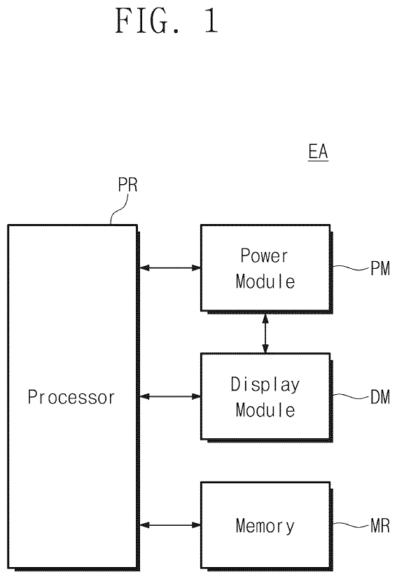

FIG. 1 is a block diagram illustrating an electronic apparatus according to some embodiments.

Referring to FIG. 1, an electronic apparatus EA according to some embodiments may include a display module DM, a processor PR, a memory MR, and a power module PM, although embodiments according to the present disclosure are not limited thereto, and the electronic apparatus EA may include additional components.

The processor PR may include at least one a central processing unit (CPU), an application processor (AP), a graphic processing unit (GPU), a communication processor (CP), an image signal processor (ISP), or a controller.

The memory MR may store data information necessary for the operation of the processor PR or the display module DM. When the processor PR runs the application stored in the memory MR, an image data signal and/or an input control signal may be transmitted to the display module DM, and the display module DM may process the transmitted signal and output the image information through the display screen. The display module DM may include a display panel to display images.

The power module PM may include a power converting module. The power converting module may convert power, which is supplied from a power supply module, such as a power adaptor or a battery device, into power necessary for the operation of the electronic apparatus EA.

At least one of components of the above-described electronic apparatus EA may be included in the display module according to embodiments and a display device, which includes the display module, according to some embodiments. In addition, some of individual modules functionally included in one module may be included in the display device, and others of the individual modules may be provided separately from the display device. For example, the display device may include the display module DM, and the processor PR, the memory MR, and the power module PM may be provided in the form of another device in the electronic apparatus EA instead of the display device.

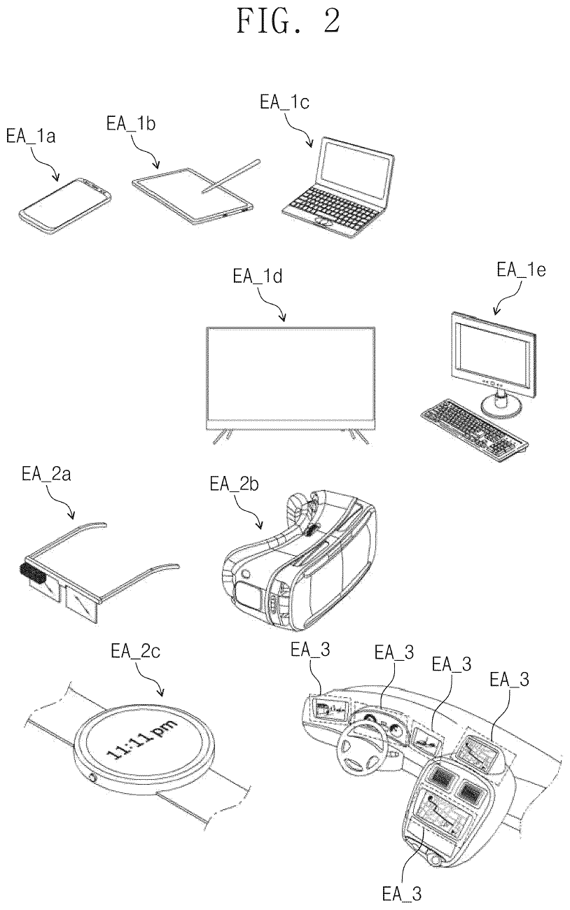

FIG. 2 is a view schematically illustrating various electronic apparatuses according to embodiments.

Referring to FIG. 2, the various electronic apparatuses including the display module according to some embodiments may include a wearable electronic apparatus such as smart glasses EA_2a, a head mounted display EA_2b, and a smart watch EA_2c, and an electronic apparatus EA-3 for the vehicle such as a center information display (CID), which is located in an instrument panel, a centerfecia, and a dashboard of a vehicle, or a room mirror display, as well as an electronic apparatus for image display such as a smartphone EA_1a, a tablet PC EA_1b, a laptop computer EA_1c, a television TV (EA_1d) and a desk monitor EA_1e.

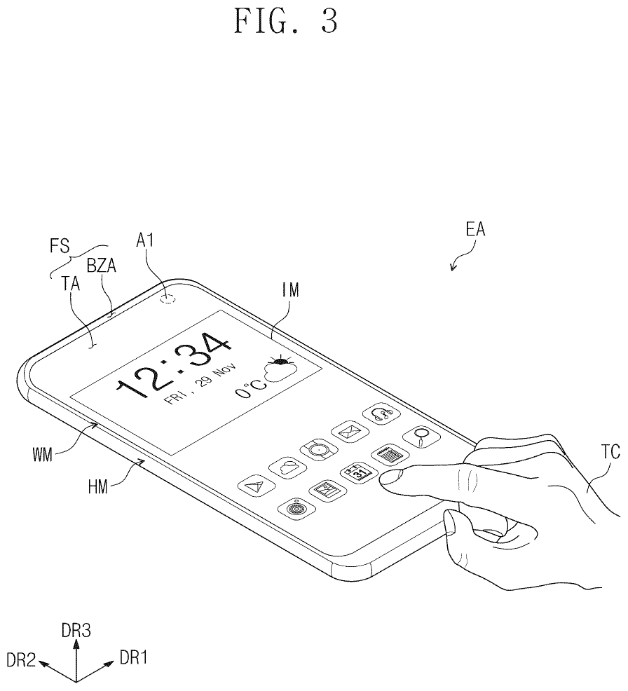

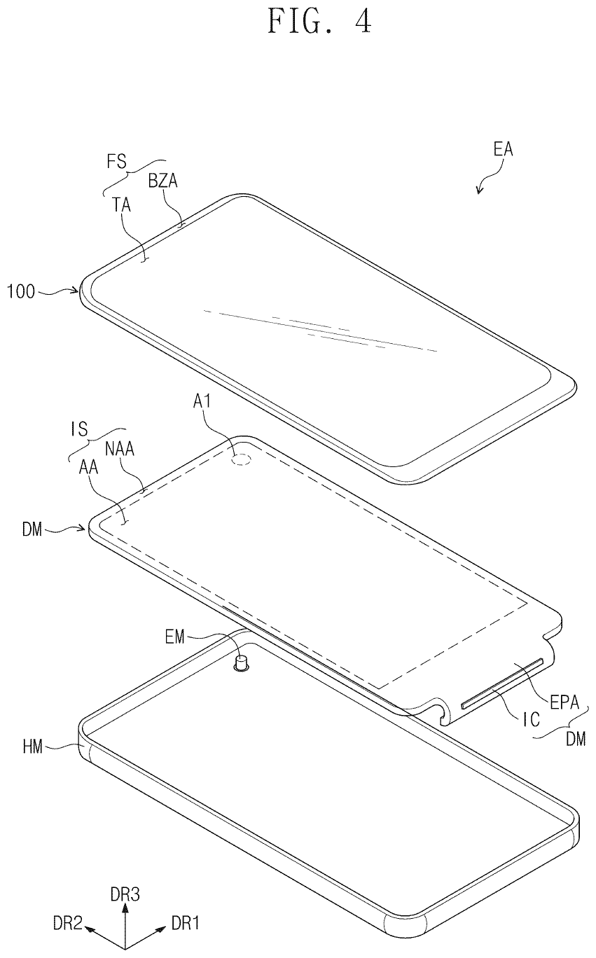

FIG. 3 is a perspective view illustrating an electronic apparatus according to some embodiments of the present disclosure. FIG. 4 is an exploded perspective view illustrating an electronic apparatus according to some embodiments of the present disclosure.

According to some embodiments, the electronic apparatus EA is illustrated as a smartphone.

The electronic apparatus EA may display an image IM on a display surface FS, which is parallel to each of a first direction DR1 and a second direction DR2, in a third direction DR3. The display surface FS for displaying an image IM may correspond to a front surface of the electronic apparatus EA and may correspond to a front surface FS of a window module WM. Hereinafter, the same reference numeral will be assigned to the display surface, and the front surface of the electronic apparatus EA, and the front surface of the window module WM. The image IM may include a still image as well as a video (or a moving picture). A clock window and icons are illustrated in FIG. 3 as an example of the image IM.

According to some embodiments, a front surface (or a top surface) and a rear surface (or a bottom surface) of each member are defined with respect to a direction in which the image IM is displayed. The front surface and the rear surface are opposite to each other in the third direction DR3, and a normal direction to each of the front surface and the rear surface may parallel to the third direction DR3. A spacing between the front surface and the rear surface in the third direction DR3 may correspond to a thickness of a display panel DP in the third direction DR3. Meanwhile, the first direction DR1, the second direction DR2, and the third direction DR3 may be relative concepts and may be changed to different directions. Hereinafter, the first to third directions are indicated by the first direction to the third direction DR1, DR2, and DR3, respectively, and refer to the same reference numerals.

The electronic apparatus EA according to some embodiments of the present disclosure may sense an input (or a user input) TC of a user, which is applied from the outside. The user input TC may include various external inputs, such as inputs made by a part of a physical body of the user, light, heat or pressure. According to some embodiments, the user input TC is illustrated as a user hand applied to the front surface. However, the user input TC described above is provided only for the illustrative purpose. For example, the user input TC may be provided in various shapes. In addition, the electronic apparatus EA may sense the user input TC applied to the side surface or the rear surface of the electronic apparatus EA depending on the structure of the electronic apparatus EA, and embodiments according to the present disclosure are not limited to any one embodiment.

A first region A1 may be defined to be overlapped with a transmissive region TA. The first region A1 may be a region defined in the display module DM to be described later, or may be a region overlapped with the display module DM when viewed in a plan view (e.g., from a view perpendicular to a display surface of the electronic apparatus EA). The electronic apparatus EA may receive an external signal required for an electronic module EM through the first region A1 or may provide a signal, which is output from the electronic module EM, to the outside through the first region A1. According to the present disclosure, because the first region A1 is provided to be overlapped with the transmissive region TA, the area of a bezel region BZA may be relatively reduced.

Referring to FIG. 4, the electronic apparatus EA may include the window module WM, a housing unit HM, the display module DM, and the electronic module EM. According to some embodiments, the window module WM is coupled to the housing unit HM to form an outer appearance of the electronic apparatus EA.

The window module WM may include an insulating panel. For example, the window module WM may include glass, plastic, or the combination thereof.

The front surface FS of the window module WM may define the front surface of the electronic apparatus EA as described above. The transmissive region TA may be an optically transparent region. For example, the transmissive region TA may be a region having at least 90% (or about 90%) of visible light transmittance.

The bezel region BZA may have a light transmittance lower than a light transmittance of the transmissive region TA. The bezel region BZA defines a shape of the transmissive region TA. The bezel region BZA may be adjacent to the transmissive region TA while surrounding the transmissive region TA.

The bezel region BZA may have a specific color. The bezel region BZA may be defined by a bezel layer separately provided from a transparent substrate for define the transmissive region TA, or may be defined by an ink layer inserted into the transparent substrate or colored on the transparent substrate.

The bezel region BZA may cover a peripheral region (or a non-display region) NAA of the display module DM to prevent or reduce visibility of the peripheral region NAA from the outside. Meanwhile, this is provided only for the illustrative purpose. For example, the bezel region BZA may be omitted from the window module WM according to some embodiments of the present disclosure.

The display module DM includes an electronic panel EPA and a driving circuit IC.

The electronic panel EPA may display the image IM and sense an external input (for example, the user input TC). The electronic panel EPA may have a front surface IS including an active region AA (or a display region) and the peripheral region NAA (or a non-display region). The active region AA may be activated in response to an electrical signal.

According to some embodiments, the active region AA may be a region for displaying the image IM and for sensing the external input TC. The active region AA may be a region for arranging a plurality of emission parts to be described in more detail later.

At least a portion of the transmissive region TA may be overlapped with the active region AA. For example, the transmissive region TA may be overlapped with an entire surface or at least a portion of the active region AA. Accordingly, the user may view the image IM through the transmissive region TA or provide the external input TC through the transmissive region TA. However, this is provided only for the illustrative purpose. For example, in the active region AA, the region for displaying the image IM may be separated from the region for sensing the external input TC. Embodiments according to the present disclosure are not limited to any one embodiment.

The peripheral region NAA may be a region covered by the bezel region BZA. The peripheral region NAA may be adjacent to the active region AA. The peripheral region NAA may surround the active region AA. The peripheral region NAA may refer to a region in which the image IM is not displayed. A driving circuit or driving line to drive the active region AA may be located in the peripheral region NAA.

According to some embodiments, a portion of the peripheral region NAA in the electronic panel EPA may be bent. For example, a portion of the peripheral region NAA may face the rear surface of the electronic apparatus EA. Accordingly, the bezel region BZA viewed on the front surface of the electronic apparatus EA may be relatively reduced. Alternatively, the electronic panel EPA may be assembled in the state that a portion of the active region AA is bent. However, this is provided only for the illustrative purpose. According to some embodiments, the electronic panel EPA may be assembled in a flat state in which the active region AA and the peripheral region NAA face the window module WM. In addition, according to some embodiments of the present disclosure, the peripheral region NAA may be omitted from the electronic panel EPA.

The active region AA (or the display region) may include the first region A1 and a second region A2. The first region A1 may be defined in a region overlapped with the electronic module EM, when viewed in a plan view. According to some embodiments, the first region A1 is illustrated in a circle shape. However, the first region A1 may have various shapes, such as a polygonal shape, an oval shape, or a figure having at least one curved side, but embodiments according to the present disclosure are not limited to any one embodiment. Further details thereof will be described later.

The second region A2 may be adjacent to the first region A1. The second region A2 may refer to a region having transmittance lower than the transmittance of the first region A1. According to some embodiments, the second region A2 has the shape of surrounding the entire portion of the edge of the first region A1 as illustrated. However, this is provided for the illustrative purpose. For example, the second region A2 may be defined to be adjacent to only a portion of an edge of the first region A1, and not limited to any one embodiment.

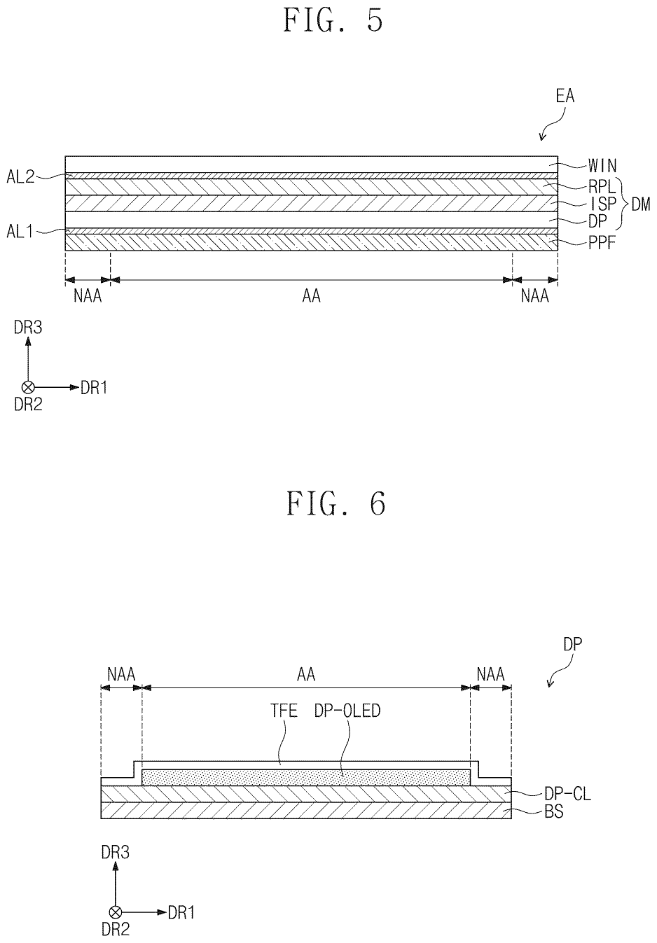

FIG. 5 is a cross-sectional view illustrating the electronic apparatus illustrated in FIG. 3. FIG. 6 is a cross-sectional view illustrating the display panel illustrated in FIG. 5.

Referring to FIG. 5, the electronic apparatus EA may include the display panel DP, an input sensor layer ISP, an anti-reflective layer RPL, a window WIN, a panel protecting film PPF, a first adhesive layer AL1, and a second adhesive layer AL2.

The display panel DP according to some embodiments of the present disclosure may be an emissive-type display panel. For example, the display panel DP may be an organic emission display panel or an inorganic emission display panel. An emission layer of the organic emission display panel may include an organic emission material. An emission layer of the inorganic emission display panel may include quantum dots or quantum rods. The following description will be made in that the display panel DP is the organic emission display panel by way of example.

Referring to FIG. 6, the display panel DP may include a substrate BS, and a circuit element layer DP-CL, a display element layer DP-OLED, and a thin film encapsulation layer TFE. The circuit element layer DP-CL, the display element layer DP-OLED, and the thin film encapsulation layer TFE may be sequentially arranged on the substrate BS.

The substrate BS may include glass or may include a flexible plastic material such as polyimide (PI).

A plurality of pixels may be located in the circuit element layer DP-CL and the display element layer DP-OLED. Each of the pixels may include a transistor located in the circuit element layer DP-CL and a light emitting element located in the display element layer DP-OLED and connected to the transistor.

The thin film encapsulation layer TFE may be located on the circuit element layer DP-CL to cover the display element layer DP-OLED. The thin film encapsulation layer TFE may protect the pixels from contaminants such as moisture, oxygen, and external foreign substances. Meanwhile, according to some embodiments, although the thin film encapsulation layer TFE covers a whole region of the substrate BS, the substrate BS may include a partial region exposed from the thin film encapsulation layer TFE according to some embodiments of the present disclosure. Alternatively, the region exposed from the thin film encapsulation layer TFE may be formed along the edge of the substrate BS, and embodiments according to the present disclosure are not limited any one embodiment.

Referring to FIG. 5, the input sensor layer ISP may be located on the display panel DP. The input sensor layer ISP may include a plurality of sensing units to sense an external input in a capacitive manner. The input sensor layer ISP may be manufactured directly on the display panel DP when the electronic apparatus EA is manufactured. For example, a conductive pattern or an insulating layer constituting the input sensor layer ISP may be directly deposited or patterned on the display panel DP. However, embodiments according to the present disclosure are not limited thereto. For example, the input sensor layer ISP may be formed in the form of a separate panel from the display panel DP and may be attached to the display panel DP through an adhesive layer.

Referring to FIG. 5, the anti-reflective layer RPL may be located on the input sensor layer ISP. The anti-reflective layer RPL may relatively reduce the reflectance of an external light of the electronic apparatus EA to relatively improve the visibility of a video displayed on the electronic apparatus EA. The anti-reflective layer RPL may include a phase retarder, a polarizer, a black matrix, or a color filter, and embodiments according to the present disclosure are not limited to any one embodiment. The anti-reflective layer RPL may be directly formed on the input sensor layer ISP through a coating process or a deposition process, or may be provided in the form of a film and bonded to the input sensor layer ISP through an adhesive layer, but embodiments according to the present disclosure are not limited thereto.

The window WIN may be located on the anti-reflective layer RPL. The window WIN may protect the display panel DP, the input sensor layer ISP, and the anti-reflective layer RPL from external scratches and impacts. The window WIN may correspond to the window module WM described above with reference to FIGS. 3 and 4.

The panel protecting film PPF may be located under the display panel DP. The panel protecting film PPF may support the display panel DP and may protect a lower portion of the display panel DP. The panel protecting film PPF may have an insulating property. For example, the panel protecting film PPF ma include a resin such as polyethyleneterephthalate (PET), polyimide (PI), or polypropylene (pp), but embodiments according to the present disclosure are not limited thereto.

The first adhesive layer AL1 may be interposed between the display panel DP and the panel protecting film PPF, and the display panel DP and the panel protecting film PPF may be combined with each other by the first adhesive layer AL1. The second adhesive layer AL2 may be interposed between the window WIN and the anti-reflective layer RPL to combine the window WIN with the anti-reflective layer RPL by the second adhesive layer AL2.

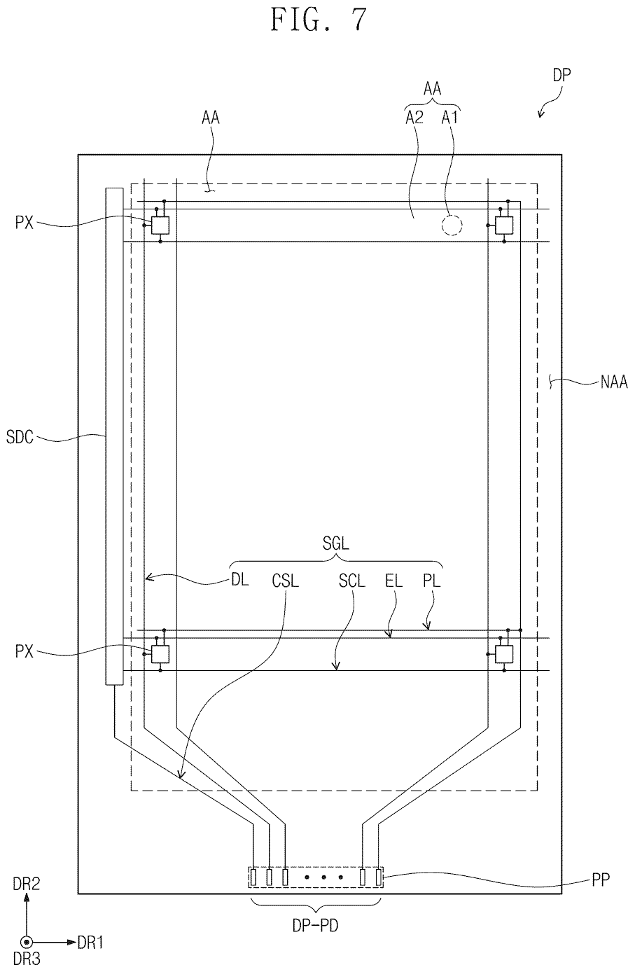

FIG. 7 is a plan view illustrating a display panel according to some embodiments of the present disclosure.

Referring to FIG. 7, the display panel DP may be defined with a display region AA and a non-display region NAA around the display region AA. The display region AA and the non-display region NAA may be distinguished from each other, depending on whether pixels PX are arranged. The pixels PX may be located in the display region AA.

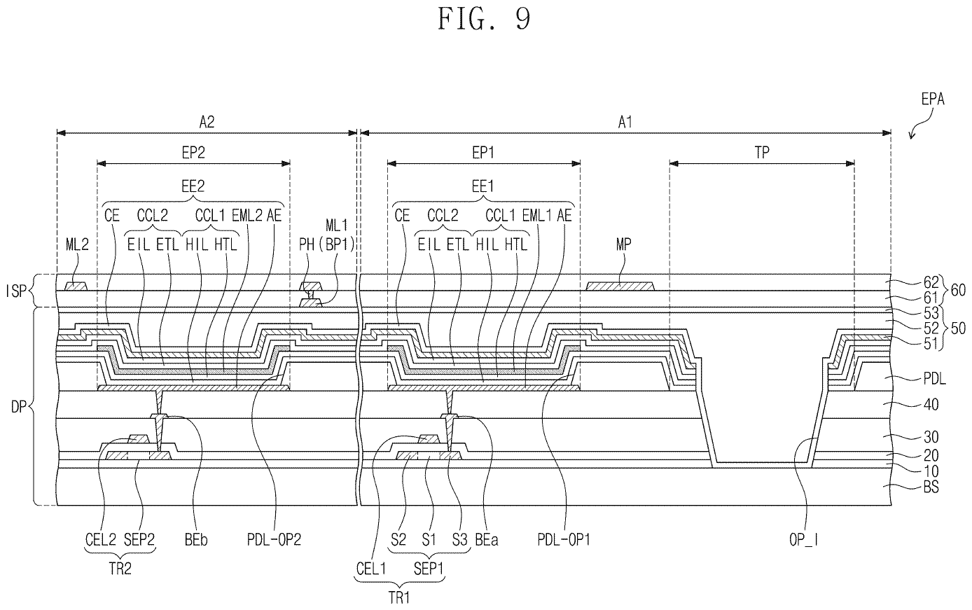

The display region AA may include the first region A1 and the second region A2. The first region A1 and the second region A2 may be distinguished from each other depending on the arrangement spacing of the pixels PX, the shape of the pixel PX or the transmissive part TP (see FIG. 9). Further details thereof will be described later.

The display panel DP may include a scan driving circuit SDC, a plurality of signal lines SGL (hereinafter, referred to as signal lines), a plurality of signal pads DP-PD, and a plurality of pixels PX.

The scan driving circuit SDC generates a plurality of scan signals (hereinafter, referred to as the “scan signals”) and sequentially outputs the scan signals to a plurality of scan lines (hereinafter referred to as the “scan lines”) SCL to be described later. The scan driving circuit SDC outputs different control signals to the pixels PX as well as the scan signals. The scan driving circuit SDC may include a plurality of transistors formed through the same process as transistors in the pixels PX.

The signal lines SGL include the scan lines SCL, data lines DL, a power line PL, emission control lines EL, and a control signal line CSL. The scan lines SCL, the data lines DL, and the emission control lines EL are connected to relevant pixels PX among the pixels PX. The power line PL may be commonly connected to the pixels PX. The control signal line CSL may provide the control signals to the scan driving circuit SDC. The power line PL may provide a voltage necessary for the operation of the pixels PX. The power line PL may include a plurality of lines that provide different voltages.

The signal pads DP-PD may be electrically connected to the data lines DL, the power line PL, and the control signal line CSL. The signal pads DP-PD may be adjacent to each other in the pad region PP defined in a partial region of the peripheral region NAA.

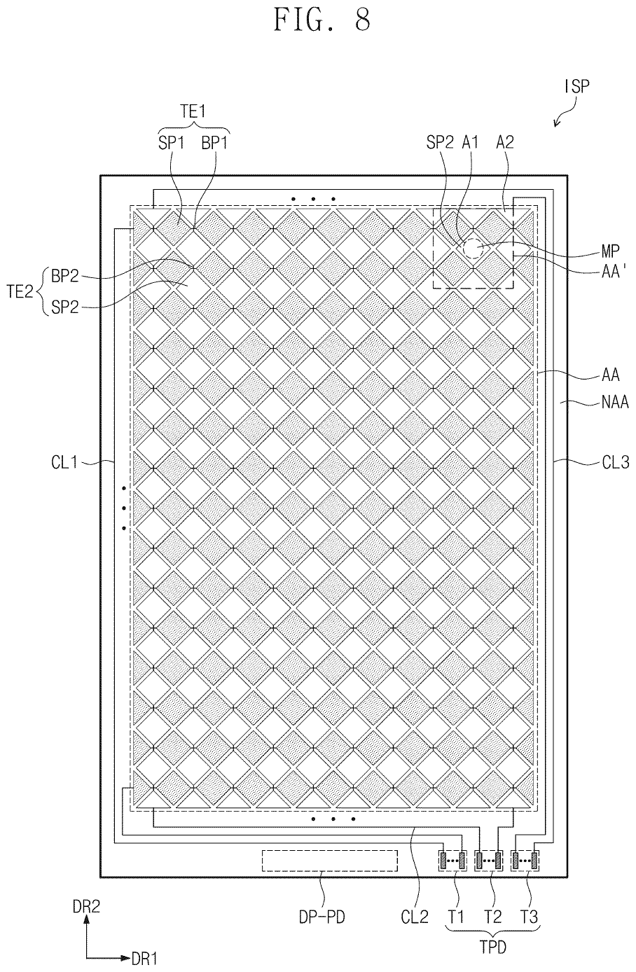

FIG. 8 is a plan view illustrating an input sensor layer according to some embodiments of the present disclosure.

The input sensor layer ISP may be located on the display panel DP (see FIG. 5). The input sensor layer ISP may sense the external input TC (see FIG. 3) to obtain the information about the position or the intensity of the external input TC. The input sensor layer ISP includes a plurality of first sensing electrodes TE1 (or first sensing electrodes), a plurality of first connection patterns BP1, a plurality of second sensing electrodes TE2 (or second electrodes), a plurality of second connection patterns BP2, a conductive pattern MP, a plurality of sensing lines CL1, CL2 and CL3, and a plurality of sensing pads TPD.

The first sensing electrodes TE1 and the second sensing electrodes TE2 may be located in the active region AA (or the display region). The input sensor layer ISP may obtain information about the external input TC based on a change in capacitance between the first sensing electrodes TE1 and the second sensing electrodes TE2.

Each of the first sensing electrodes TE1 may extend in the first direction DR1 and may be arranged in the second direction DR2. Each of the first sensing electrodes TE1 may include a first sensing pattern SP1 and a first connection pattern BP1.

The first sensing pattern SP1 may be located in the display region AA. According to some embodiments, the first sensing pattern SP1 may have a rhombus shape. However, this is provided for the illustrative purpose. For example, the first sensing pattern SP1 may have various shapes, and not limited to any one embodiment.

According to some embodiments, the first connection patterns BP1 may extend in the first direction DR1. Each of the first connection patterns BP1 may be connected to the first sensing pattern SP1. One first connection pattern BP1 may be interposed between two first sensing patterns SP1 to connect the two first sensing patterns SP1.

Each of the second sensing electrodes TE2 may extend in the second direction DR2 and may be arranged in the first direction DR1. Each of the second sensing electrodes TE2 may include the second sensing pattern SP2 and the second connection pattern BP2.

The second sensing pattern SP2 may be located in the display region AA. According to some embodiments, the second sensing pattern SP2 may have the same shape as the first sensing pattern SP1. For example, the second sensing pattern SP2 may have a rhombus shape. However, this is provided only for the illustrative purpose. The second sensing pattern SP2 may have various shapes, and embodiments according to the present disclosure are not limited to any one embodiment.

According to some embodiments, the second connection pattern BP2 may extend in the second direction DR2. The second connection pattern BP2 may be connected to the second sensing pattern SP2. The second connection pattern BP2 may be interposed between two second sensing patterns SP2 to connect the two second sensing patterns SP2 to each other.

The sensing lines CL1, CL2, and CL3 may be located in the peripheral region NAA. The sensing lines CL1, CL2, and CL3 may include first sensing lines CL1, second sensing lines CL2, and third sensing lines CL3. The first sensing lines CL1 may be connected to the first sensing electrodes TE1, respectively. The second sensing lines CL2 may be connected to one ends of the second sensing electrodes TE2, respectively.

The third sensing lines CL3 may be connected to opposite ends of the second sensing electrodes TE2, respectively. The opposite ends of the second sensing electrodes TE2 may be portions facing the one ends of the second sensing electrodes TE2. According to the present disclosure, the second sensing electrodes TE2 may be connected to the second sensing lines CL2 and the third sensing lines CL3. Accordingly, the sensitivity depending on the region may be uniformly maintained with respect to the second sensing electrodes TE2 having a longer length than the first sensing electrodes TE1. Meanwhile, this is provided only for the illustrative purpose. For example, the third sensing lines CL3 may be omitted, and embodiments according to the present disclosure are not limited to any one embodiment.

The sensing pads TPD may be located in the peripheral region NAA. The sensing pads TPD may include first sensing pads T1, second sensing pads T2, and third sensing pads T3. The first sensing pads T1 may be respectively connected to the first sensing lines CL1 to provide an external signal to the first sensing electrodes TE1. The second sensing pads T2 may be connected to the second sensing lines CL2, respectively, and the third sensing pads T3 may be connected to the third sensing lines CL3, respectively, to be electrically connected to the second sensing electrodes TE2.

A conductive pattern MP may be located in the first region A1. Referring to FIG. 8, the first region A1 may be adjacent to any one of the first sensing electrodes TE1 when viewed in a plan view. However, embodiments according to the present disclosure are not limited thereto. The first region A1 may be adjacent to any one of the second sensing electrodes TE2 when viewed in a plan view. In this case, the conductive pattern MP may be electrically connected to the first sensing electrodes TE1 or the second sensing electrodes TE2, and may be insulated from the first sensing electrodes TE1 or the second sensing electrodes TE2. Further details thereof will be described later.

FIG. 9 is a cross-sectional view of an electronic apparatus according to some embodiments of the present disclosure; FIG. 9 illustrates a portion of the first region A1 and a portion of the second region A2.

Referring to FIG. 9, the electronic apparatus EA may include the display panel DP and the input sensor layer ISP.

The display panel DP may include the substrate BS, a plurality of insulating layers 10, 20, 30, 40, and 50, a pixel defining layer PDL, an emission part EP, and a transmissive part TP.

The substrate BS may be optically transparent and may have an insulating property. For example, the substrate BS may include a multi-layer structure including glass, plastic, polymer film, or an organic film and an inorganic film.

The insulating layers 10, 20, 30, 40, and 50 may be stacked on the substrate BS. The insulating layers 10, 20, 30, 40, and 50 may include the first to fifth insulating layers 10, 20, 30, 40, and 50. Each of the first to fifth insulating layers 10, 20, 30, 40, and 50 may be an organic film or an inorganic film. Meanwhile, the display panel DP may include an additional insulating layer, in addition to the five insulating layer. However, embodiments according to the present disclosure are not limited to any one embodiment.

The pixel defining layer PDL may be located on the fifth insulating layer 50. Emission openings PDL-OP1 and PDL-OP2 may be defined in the pixel defining layer PDL. The emission openings PDL-OP1 and PDL-OP2 may correspond to anodes AE to be described later, and the pixel defining layer PDL may at least partially expose the anodes AE through the emission openings PDL-OP1 and PDL-OP2.

The pixel defining layer PDL may include an inorganic insulating material. For example, the pixel defining layer PDL may include a silicon nitride SiNx.

The emission part EP1 and EP2 may include a light emitting element EE1 and EE2 and a thin film transistor TR1 and TR2.

The thin film transistor TR1 and TR2 may include a semiconductor pattern SP and control electrodes CEL1 and CEL2.

The semiconductor patterns SEP1 and SEP2 may be located between the first insulating layer 10 and the second insulating layer 20. The semiconductor patterns SEP1 and SEP2 may include a channel part S1, an input part S2, and an output part S3. The channel part S1, the input part S2, and the output portion S3 may be divided on a plane of the semiconductor pattern SP. The channel part S1 may have lower conductivity than conductivity of the input part S2 and the output part S3.

According to some embodiments, the input part S2 and the output part S3 may include relatively reduced metal. The input part S2 and the output part S3 may function as a source electrode and a drain electrode of the thin film transistor TR. However, this is provided only for the illustrative purpose. The thin film transistor TR may further include a source electrode and a drain electrode making contact with the input part S2 and the output part S3. Embodiments according to the present disclosure are not limited to any one embodiment.

The control electrodes CEL1 and CEL2 may have conductivity. The control electrodes CEL1 and CEL2 may be spaced apart from the semiconductor patterns SEP1 and SEP2, respectively, while interposing the second insulating layer 20 between the control electrode CEL1 and the semiconductor pattern SEP1, and between the control electrode CEL2 and the semiconductor pattern SEP2. The control electrodes CEL1 and CEL2 may be overlapped with channel parts S1 of the semiconductor patterns SEP1 and SEP2 when viewed in a plan view.

The light emitting element EE may be located on the thin film transistor TR. The light emitting element EE may be located on the fourth insulating layer 40, and may be connected to the thin film transistor TR through connection electrodes BEa and BEb separately provided.

The connection electrodes BEa and BEb may be formed through the second insulating layer 20 and the third insulating layer 30 to be connected to the output part S3 of the thin film transistor TR. The light emitting element EE may be formed through the fourth insulating layer 40 to be connected to the connection electrode BE. Meanwhile, this is provided only for the illustrative purpose. In the display panel DP according to some embodiments of the present disclosure, the connection electrodes BEa and BEb may be located at mutually different positions or may be omitted. However, embodiments according to the present disclosure are not limited any one embodiment.

The light emitting element EE includes the anode AE, a cathode CE, an emission layer EML, and charge control layers CCL1 and CCL2. The charge control layers CCL1 and CCL2 may include a first charge control layer CCL1 and a second charge control layer CCL2.

The anode AE may be interposed between the fourth insulating layer 40 and the fifth insulating layer 50. At least a portion of the anode AE may be exposed by an emission opening PDL-OP1 and PDL-OP2.

The emission layer EML may be located on the anode AE. The emission layer EML may be referred to as an “organic layer” or an “intermediate layer”. The emission layer EML may cover a portion of a top surface of the pixel defining layer PDL. The emission layer EML includes a low-molecular-weight organic light emitting material or a high-molecular-weight organic light emitting material, and may include fluorescence or phosphorescence. Alternatively, the emission layer EML may include an inorganic light emitting material such as quantum dots, nano-rods, micro LEDs, and nano LEDs. According to some embodiments of the present disclosure, the light emitting element EE may include various light emitting materials as long as the various light emitting materials may generate light, and embodiments according to the present disclosure are not limited to any one embodiment.

The cathode CE may be located on the emission layer EML. The cathode CE may cover the emission layer EML. The cathode CE may be located on the charge control layers CCL1 and CCL2. The cathode CE may be integrally formed on the front surface of the display panel DP. However, this is provided only for the illustrative purpose. The cathode CE, which is in the form similar to that of the anode AE, may be patterned and formed for each emission part EP, and embodiments according to the present disclosure are not limited to any one embodiment.

The first charge control layer CCL1 may be located between the anode AE and the emission layer EML. The first charge control layer CCL1 may include a hole injection region HIL (or a hole injection layer) and a hole transport region HTL (or a hole transport layer). According to some embodiments, it is illustrated that the first charge control layer CCL1 includes the hole injection layer HIL and the hole transport layer HTL. The first charge control layer CCL1 may be formed as a common layer with respect to the entire surface of the display panel DP using an open mask.

The second charge control layer CCL2 may be located between the emission layer EML and the cathode CE. The second charge control layer CCL2 may include an electron injection region EIL (or an electron injection layer) and an electron transport region ETL (or an electron transport layer). According to some embodiments, it is illustrated that the second charge control layer CCL2 includes the electron injection layer EIL and the electron transport layer ETL. The second charge control layer CCL2 may be formed as a common layer with respect to the entire surface of the display panel DP using an open mask.

The transmissive part TP may be located in the first region A1. In other words, the display panel DP may further include the transmissive part TP in the first region A1, which is different from the second region A2. In this case, the first region A1 may be a region having a transmittance higher than a transmittance of the second region A2. Further details thereof will be described later.

The fifth insulating layer 50 may be located on the pixel defining layer PDL. The fifth insulating layer 50 may be an encapsulation layer. The fifth insulating layer 50 may include a first inorganic layer 51, an organic layer 52, and a second inorganic layer 53. However, embodiments according to the present disclosure are not limited thereto. For example, the fifth insulating layer 50 may further include a plurality of inorganic layers and organic layers.

The first inorganic layer 51 may cover the cathode CE. In addition, the first inorganic layer 51 may cover an inner surface of an opening OP_I. The first inorganic layer 51 may prevent or reduce instances of external contaminants such as moisture or oxygen infiltrating into the light emitting element EE. For example, the first inorganic layer 51 may include a silicon nitride, a silicon oxide, or the combination thereof. The first inorganic layer 51 may be formed through a deposition process.

The organic layer 52 may include the first inorganic layer 51 while making contact with the first inorganic layer 51. The organic layer 52 may provide a flat surface on the first inorganic layer 51. The roughness formed on a top surface of the first inorganic layer 51 or particles present on the first inorganic layer 51 are covered by the organic layer 52, thereby preventing or reducing a surface state of the top surface of the first inorganic layer 51 exerting an influence on components formed on the organic layer 52. In addition, the organic layer 52 may release the stress between layers making contact with each other. The organic layer 52 may include an organic material and may be formed through a solution process such as a spin coating process, a slit coating process, or an inkjet process.

The second inorganic layer 53 may be located on the organic layer 52. The second inorganic layer 53 may cover the organic layer 52. When the second inorganic layer 53 is located on the organic layer 52, the second inorganic layer 53 may be stably formed on a flatter surface than when the second inorganic layer 53 is located directly on the first inorganic layer 51. The second inorganic layer 53 may seal moisture discharged from the organic layer 52 to prevent or reduce the moisture flowing out. For example, the second inorganic layer 53 may include a silicon nitride, a silicon oxide, or the combination thereof. The second inorganic layer 53 may be formed through a deposition process.

The input sensor layer ISP may include a plurality of conductive patterns. The input sensor layer ISP may include at least one conductive layer (or at least one sensor conductive layer) including conductive patterns and at least one insulating layer (or at least one sensor insulating layer). According to some embodiments, the input sensor layer ISP may include a first sensor conductive layer ML1, a first sensor insulating layer 61, a second sensor conductive layer ML2, and a second sensor insulating layer 62.

The first sensor conductive layer ML1 may be located on the fifth insulation layer 50. The second sensor conductive layer ML2 may be located on the first sensor conductive layer ML1. Each of the first sensor conductive layer ML1 and the second sensor conductive layer ML2 may have a single-layer structure or a multi-layer structure in which layers are stacked in the third direction DR3. The first sensor conductive layer ML1 and the second sensor conductive layer ML2 may include conductive lines to define a mesh-shaped electrode. The conductive line of the first sensor conductive layer ML1 and the conductive line of the second sensor conductive layer ML2 may or may not be connected to each other through a contact hole PH formed through the first sensor insulating layer 61, depending on positions.

The first sensor conductive layer ML1 and the second sensor conductive layer ML2 which are in a single-layer structure, may include a metal layer or a transparent conductive layer. The metal layer may include molybdenum (Mo), silver (Ag), titanium (Ti), copper (Cu), aluminum (Al), or the alloys thereof. The transparent conductive layer may include a transparent conductive oxide such as an indium tin oxide (ITO), an indium zinc oxide (IZO), a zinc oxide (ZnOx), or an indium zinc tin oxide (IZTO). In addition, the transparent conductive layer may include a conductive polymer such as PEDOT, metal nano-wires, or graphene.

Each of the first sensor conductive layer ML1 and the second sensor conductive layer ML2 may include at least some of the first and second sensing electrodes TE1 and TE2, the first and second connection patterns BP1 and BP2, and the conductive pattern MP described above with reference to FIG. 7. In this case, the first and second sensing electrodes TE1 and TE2 and the first and second connection patterns BP1 and BP2 may be located in the second region A2, and the conductive pattern MP may be located in the first region A1.

The conductive pattern MP illustrated in FIG. 9 may correspond to the conductive pattern MP in FIG. 7. The conductive pattern MP may be provided on a layer interposed between the first sensor insulating layer 61 and the second sensor insulating layer 62. However, embodiments according to the present disclosure are not limited thereto. The conductive pattern MP may include a plurality of patterns. The patterns may be provided on the plurality of layers, for example, an upper portion of the fifth insulating layer 50 and the first sensor insulating layer 61.

According to some embodiments, the conductive pattern MP may be provided to be in a non-overlap with the transmissive part TP and the emission part EP. Accordingly, even if the conductive pattern MP is optically opaque, the conductive pattern MP may not exert an influence on light emission in the emission part EP or transmittance in the transmissive part TP. Meanwhile, this is provided only for illustrative purpose. When the conductive pattern MP is optically transparent, the conductive pattern MP may be overlapped with the transmissive part TP or the emission part when viewed in a plan view, and embodiments according to the present disclosure are not limited thereto. Further details of the conductive pattern MP located in the first region A1 will be described later.

FIG. 9 illustrates embodiments in which the first connection patterns BP1 form the first sensor conductive layer ML1, and the first sensing patterns SP1, the second sensing patterns SP2, the second connection patterns BP2, and the conductive pattern MP form the second sensor conductive layer ML2. However, the present disclosure is provided only for the illustrative purpose. For example, the conductive patterns forming the first sensor conductive layer ML1 and the second sensor conductive layer ML2 may have various combinations and embodiments according to the present disclosure are not limited to any one embodiment.

The first sensor insulating layer 61 may be interposed between the first sensor conductive layer ML1 and the second sensor conductive layer ML2. The first sensor insulating layer 61 may be located between the second sensor conductive layer ML2 and the fifth insulating layer 50. The second sensor insulating layer 62 may be located on the first sensor insulating layer 61. The second sensor insulating layer 61 may cover a plurality of conductive patterns included in the first sensor conductive layer ML1. The first sensor insulating layer 61 may include at least one of a silicon nitride, a silicon oxide, a silicon oxynitride, or an aluminum oxide. In this case, the first sensor insulating layer 61 may be provided in the form of a plurality of inorganic layers. However, embodiments according to the present disclosure are not limited to an embodiment, and the first sensor insulating layer 61 may include an organic insulating material. In this case, the first sensor insulating layer 61 may be provided in the form of a single layer. In other words, the first sensor insulating layer 61 may include an inorganic layer or an organic layer.

The second sensor insulating layer 62 (or the sensor cover layer) may cover a plurality of conductive patterns included in the second sensor conductive layer ML2. According to some embodiments of the present disclosure, the second sensor insulating layer 62 may be omitted. The second sensor insulating layer 62 may be replaced with an adhesive layer or an insulating layer of an optical layer located on the input sensor layer ISP. In other words, the first sensor insulating layer 61 and the second sensor insulating layer 62 may include an inorganic layer or an organic layer.

According to the present disclosure, as described above, the display region AA of the display panel DP may include the first region A1 and the second region A2 having a transmittance lower than the transmittance of the first region A1. In this case, a first emission part EP1 and the transmissive part TP may be located in the first region A1. In other words, the first region A1 may further include the transmissive part TP, which is different from the second region A2. Accordingly, the first region A1 may be provided to display the image IM and have a higher transmittance.

The transmissive part TP may be spaced apart from the emission parts EP1 and EP2. The transmissive part TP may be formed by removing regions, which correspond to the transmissive part TP, of the first to fourth insulating layers 10, 20, 30, and 40 and the pixel defining layer PDL. For example, the specific opening OP_I may be formed in the first to fourth insulating layers 10, 20, 30, and 40, to expose the substrate BS, and the emission layer EML and the cathode CE are removed from the opening OP_I, thereby forming the transmissive part TP having the transmittance higher than the transmittance of the emission parts EP1 and EP2.

The transmissive part TP may have the transmittance higher than the transmittance of the emission parts EP1 and EP2, as the first to fourth insulating layers 10, 20, 30, and 40 are removed through the opening OP_I and layers, which are located in the first region A1, forming the light emitting element EE1 are removed. Meanwhile, this is provided only for the illustrative purpose. For example, the transmissive part TP may further include some of the charge control layers CCL1 and CCL2, as long as the transmissive part TP has the transmittance higher than the transmittance of the emission part EP. However, embodiments according to the present disclosure are not limited to any one embodiment.

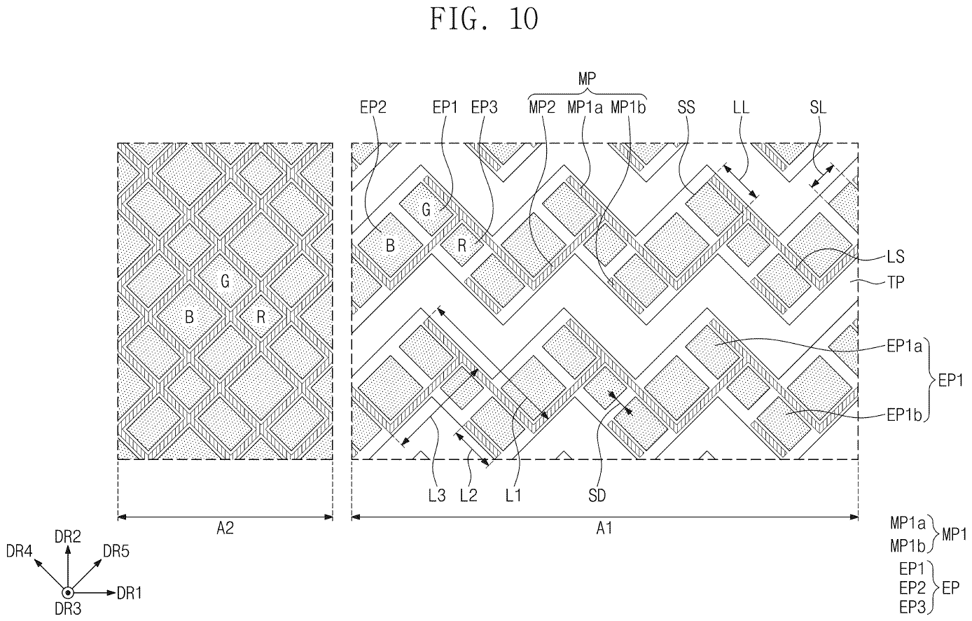

FIG. 10 is an enlarged plan view illustrating a partial region of an electronic apparatus. FIG. 10 illustrates an enlarged partial region of the first region A1 and an enlarged partial region of the second region A2 for the convenience of explanation. In addition, FIG. 10 illustrates the input sensor layer ISP together, when viewed from above the display surface IS (see FIG. 4) of the display module DM (see FIG. 4).

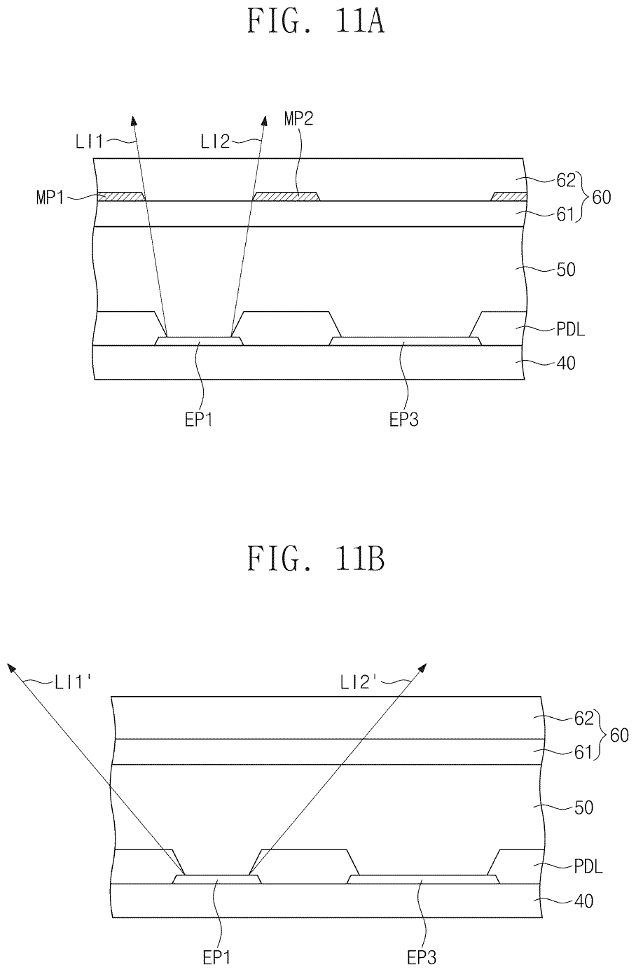

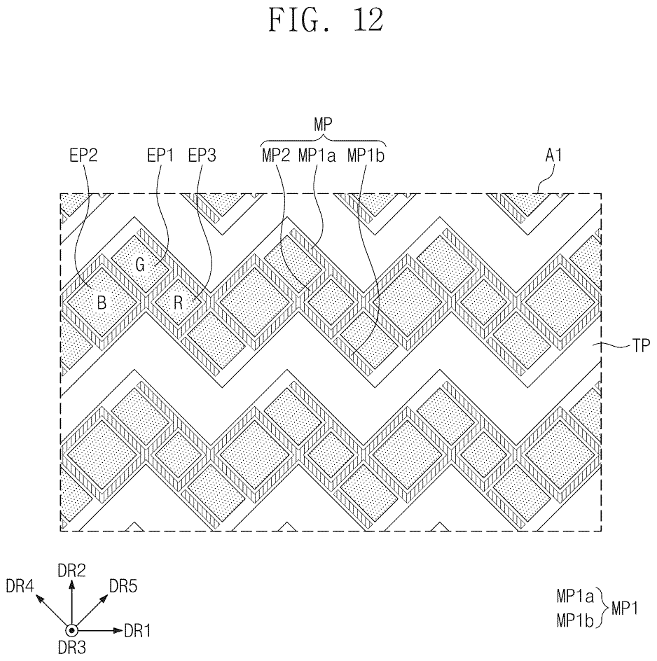

FIG. 11A is a cross-sectional view illustrating an electronic apparatus according to some embodiments of the present disclosure. FIG. 11B is a cross-sectional view illustrating an electronic apparatus according to a comparative example. FIGS. 11A and 11B illustrate the route of light emitted from the first emission part. FIG. 11B illustrates the case that a conductive pattern is not located to be adjacent to longer sides of the first emission parts, which is different from FIG. 11A.

In the following description made with reference to FIGS. 10 to 11B, the same/similar reference numerals will be assigned to components the same/similar to components described with reference to FIGS. 8 and 9 and the redundant duplication will be omitted.

Referring to FIG. 10, the display panel DP (see FIG. 5) may include the emission part EP and the transmissive part TP. The shape of the emission part EP when viewed in a plan view corresponds to an emission region of one light emitting element EE to be described later. According to some embodiments, the emission part EP is illustrated in the shape of a rectangle. The emission part EP may include a plurality of emission parts, and may be spaced apart from each other in the active region AA.

Each of the plurality of emission parts EP may include a first emission part EP1, a second emission part EP2, and a third emission part EP3. The first emission parts EP1 may emit light in a first color. The second emission parts EP2 may emit light of a second color different from the light in the first color. The third emission parts EP3 may emit light in a third color different from the light in the first and second colors. In this case, the light in the first color may be green light, the light in the second color may be blue light, and the light in the third color may be red light. However, embodiments according to the present disclosure are not limited thereto.

Referring to FIG. 10, each of the first emission parts EP1 may include sides LS and SS having different lengths when viewed in a plan view. For example, the first emission part EP1 may include the longer side LS and the shorter side SS having a length shorter than a length of the longer side LS. In this case, the longer side LS of the first emission part EP1 may extend in a first diagonal direction DR4, and the shorter side SS of the first emission part EP1 may extend in a second diagonal direction DR5 crossing the first diagonal direction DR4. Although FIG. 10 illustrates that each of the first emission parts EP1 has the shape of a rectangle when viewed in a plan view, embodiments according to the present disclosure are not limited thereto. The first emission part EP1 may have an elliptical shape having a minor axis and a major axis, when viewed in a plan view.

Each of the second emission parts EP2 may include sides having an equal length. The second emission parts EP2 may be located on the longer sides LS of the first emission parts EP1. The second emission parts EP2 may be adjacent to the longer side LS of the first emission parts EP1. In this case, the length of each side of the second emission part EP2 may be equal to the length LL of the longer side LS of the first emission part EP1. Although FIG. 10 illustrates that each of the second emission parts EP2 has the shape of a square when viewed in a plan view, embodiments according to the present disclosure are not limited thereto. The second emission part EP2 may have a circle shape, when viewed in a plan view.

Each of the third emission parts EP3 may include sides having an equal length. The third emission parts EP3 may be located at the shorter sides SS of the first emission parts EP1. The third emission parts EP3 may be adjacent to the shorter sides SS of the first emission parts EP1. In this case, the length of each side of the third emission part EP3 may be equal to the length SL of the shorter side SS of the first emission part EP1. Although FIG. 10 illustrates that each of the third emission parts EP3 has the shape of a square when viewed in a plan view, embodiments according to the present disclosure are not limited thereto. The third emission part EP3 may have a circle shape, when viewed in a plan view.

The transmissive part TP may be located in the first region A1 and my not be located in the second region A2 as described above. The transmissive part TP may include a plurality of transmissive parts which are spaced apart from each other. In addition, the plurality of transmissive parts TP may be spaced apart from the first to third light emission parts EP1, EP2, and EP3. As illustrated in FIG. 10, the plurality of transmissive parts TP have a zig-zag pattern, when viewed in a plan view. However, embodiments according to the present disclosure are not limited thereto. For example, the transmissive parts TP may have various shapes.

Referring to FIG. 10, according to the present disclosure, the input sensor layer ISP may include the first sensing electrodes TE1, the second sensing electrodes TE2, and the conductive pattern MP.

FIG. 10 illustrates an enlarged portion of a sensing electrode located in the second region A2 and an enlarged portion of the conductive pattern MP located in the first region A1 for the convenience of explanation.

Referring to FIG. 10, the conductive pattern MP may be located in the first region A1. The conductive pattern MP may include first patterns MP1 and second patterns MP2.

Each of the first patterns MP1 may be a pattern extending in the first diagonal direction DR4 (or a fourth direction). In this case, the fourth direction DR4 may refer to a direction tilted with respect to the first direction DR1 and the second direction DR2. According to some embodiments, it is illustrated that the fourth direction DR4 is tilted at 135° with respect to the first direction DR1. However, this is provided only for the illustrative purpose. When the fourth direction DR4 is tilted with respect to the first direction DR1 and the second direction DR2, the fourth direction DR4 may have various tilting angles, and embodiments according to the present disclosure are not limited to any one embodiment.

Each of the first patterns MP1 may be located adjacent to at least any one longer side LS of the longer sides LS of the first emission parts EP1. According to some embodiments, the first patterns MP1 may include a plurality of first sub-patterns MP1a and a plurality of second sub-patterns MP1b.

Each of the first sub-patterns MP1a is located adjacent to a side, which faces the transmissive part TP in a fifth direction DR5, of the first emission part EP1a of the first emission parts EP1. Each of the first sub-patterns MP1a may block light, which is output in the fifth direction DR5 and leaks to the transmissive part TP, of light emitted from the first emission part EP1a.

Each of the second sub-patterns MP1b is located adjacent to a side, which faces the transmissive part TP in a direction opposite to the fifth direction DR5, of the first emission part EP1b of the first emission parts EP1. In other words, each second sub-pattern MP1b may be arranged in the direction opposite to the fifth direction DR5, with respect to the first emission part EP1b adjacent to the second sub-pattern MP1b. Each of the second sub-patterns MP1b may block light, which is output in the direction opposite to the fifth direction DR5 and leaks to the transmissive part TP, of light emitted from the second emission part EP1b.

Referring to FIGS. 11A and 11B, when each of the first and second sub-patterns MP1a and MP1b is located at a side, which faces the transmissive part TP, of the first emission part EP1, each of the first and second sub-patterns MP1a and MP1b may more restrict the path of light LI1 (hereinafter, a first light) emitted from the first emission part EP1 toward the transmissive part TP and passing through the sensor insulating layer 60 to be viewed, as compared to when each of the first and second sub-patterns MP1a and MP1b is not located at the side, which faces the transmissive part TP, of the first emission part EP1. In other words, a portion of light to be viewed at a side of the transmissive part TP may be blocked by the conductive pattern MP. First light LI1′ in FIG. 11B may be diffused toward the transmissive part TP without the restriction of the path of the first light LI1′, as a component, such as the conductive pattern, is absent above the first emission part EP1, while a portion of the first light LI1 in FIG. 11A may be blocked from leaking toward the transmissive part TP by the conductive pattern CP. In other words, the first and second sub-patterns MP1a and MP1b may block or scatter the portion of the light LI1 output toward the transmissive part TP to perform a shielding function.

According to some embodiments, an amount of light emitted from the first emission part EP1 toward the longer side LS, which faces the transmissive part TP, of the first emission part EP1 may be larger than an amount of light emitted from the first emission part EP1 toward the shorter side SS, which faces the transmissive part TP, of the first emission part EP1. In other words, according to some embodiments of the present disclosure, the electronic apparatus EA may have a higher brightness in the direction of the longer side LS, which faces the transmissive part TP, of the first emission part EP1 and may have a brightness value varied depending on angles of direction. In this case, as the first and second sub-patterns MP1a and MP1b are located at the longer sides LS, which face the transmissive part TP, of the first emission part EP1, as described above, a portion of light output in the direction of the longer side LS toward the transmissive part TP may be blocked. Accordingly, a constant amount of light may be emitted from the first emission part EP1 at whole angles of direction, and the difference in brightness between angles of direction may be relatively reduced in the first emission part EP1 including the longer side LS and the shorter side SS.

Meanwhile, each of the first sub-patterns MP1a may have a first length L1. The first length L1 may be longer than a length LL of the longer side LS of the first emission part EP1. According to some embodiments, one first sub-pattern MP1a may extend to be adjacent to sides of two first emission parts EP1 and the third emission part EP3 arranged in the fourth direction DR4. Accordingly, the first length L1 may be at least the sum of lengths of the longer sides LS of the two first emission parts EP1 and the length of the third emission part EP3. Accordingly, the first sub-pattern MP1a may block light, which is output in the fifth direction DR5 and leaks through the transmissive part TP, of light emitted from the two first emission parts EP1 and the third emission part EP3. Accordingly, light may be blocked from leaking through a wide range, thereby preventing or reducing degradation of light transmittance in the first region A1.

In addition, as the first sub-patterns MP1a extend to be adjacent to the sides of the two first emission parts EP1 and the third emission part EP3, two second patterns MP2 spaced apart from each other may be electrically connected to each other. In this case, the first sub-patterns MP1a and the second patterns MP2 may be electrically connected to the first sensing electrodes TE1 or the second sensing electrodes TE2 as a whole. Accordingly, the number of conductive patterns functioning as the sensing electrode may be increased, thereby relatively improving the sensitivity. Meanwhile, this is provided only for the illustrative purpose. The first sub-pattern MP1a may have various lengths, as long as the first sub-pattern MP1a is located at a side, which faces the transmissive part TP, of the first emission part EP1a, and embodiments according to the present disclosure are not limited to any one embodiment.

According to some embodiments, each second sub-pattern MP1b may have a second length L2 shorter than the first length L1. In this case, the second length L2 may be at least adjacent to the longer side LS of the first emission part EP1, without reaching a side of the second emission part EP2 adjacent to the first emission part EP1. In other words, the second length L2 may range from the length LL of the long side LS of the first emission part to the sum of the length LL of the longer side LS of the first emission part EP1 and a spacing SD from the second emission part EP2 adjacent. For example, some of the second sub-patterns MP1b may have a length equal to the length of the longer side LS of the first emission part EP1.

According to the disclosure, an area of the second sub-pattern MP1b occupied in the first region A1 is minimized, thereby blocking light from leaking and relatively improving the transmittance of the first region A1. Meanwhile, this is provided only for the illustrative purpose. The second sub-pattern MP1b may have various lengths depending on the design of light transmittance of the first region A1, and embodiments according to the present disclosure are not limited to any one embodiment.

Referring to FIG. 10, each second sub-pattern MP1b may be arranged to be spaced apart from the first sub-patterns MP1a. Although FIG. 10 illustrates that the second sub-pattern MP1b is spaced apart from the second pattern MP2, each second sub-pattern MP1b may extend in the fourth direction DR4 and may be connected to the second pattern MP2. However, embodiments according to the present disclosure are not limited any one embodiment.

Each second pattern MP2 may be a pattern extending in the second diagonal direction DR5 (or a fifth direction). The fifth direction DR5 may be a direction perpendicular to the fourth direction DR4 while crossing the fourth direction DR4. According to some embodiments, it is illustrated that the fifth direction DR5 is titled at 45° with respect to the first direction DR1. However, this is provided only for the illustrative purpose. When the fifth direction DR5 is tilted with respect to the first direction DR1 and the second direction DR2, the fifth direction DR5 may have various tilting angles, and embodiments according to the present disclosure are not limited to any one embodiment.

Each of the second patterns MP2 may be arranged to be adjacent to a side, which faces the transmissive part TP in the direction opposite to the fourth direction DR4, of sides of the second emission parts EP2, and a side, which faces the first emission part EP1 in the fourth direction DR4, of sides of the third emission parts EP3. Accordingly, each of the second patterns MP2 may block light, which is output in the direction opposite to the fourth direction DR4 and leaks through the transmissive part TP, of light emitted from the second emission part EP2, and light which is output in the fourth direction DR4 and leaks to the first emission part EP1, of light emitted from the third emission part EP3.

Referring to FIGS. 11A and 11B, when the second pattern MP2 may be located adjacent to a side, which faces the first emission part EP1 in the fourth direction DR4, of sides of the third emission parts EP3, the second pattern MP2 may more restrict the path of light LI2 (hereinafter, a second light) emitted from the first emission part EP1 toward the third emission part EP3 and passing through the sensor insulating layer 60 to be viewed, as compared to when the second pattern MP2 is not located adjacent to the side, which faces the first emission part EP1 in the fourth direction DR4, of the sides of the third emission parts EP3. In other words, a portion of light to be viewed at a side of the third emission part EP3 may be blocked by the conductive pattern MP. For example, second light LI2′ in FIG. 11B may be diffused toward the transmissive part TP without the restriction of the path of the second light LI2′, as a component, such as the conductive pattern, is absent above, while a portion of the second light LI2 in FIG. 11A may be blocked from leaking toward the third emission part EP3 by the conductive pattern MP. In other words, the second pattern MP2 may block or scatter the portion of the second light LI2 output toward the second emission part EP2 to perform a shielding function.

Referring to FIG. 10, the second pattern MP2 may not be located adjacent to a side, which faces the transmissive part TP in the fourth direction DR4, of the first emission part EP1a of the first emission parts EP1. Similarly, the second pattern MP2 may not be located adjacent to a side, which faces the transmissive part TP in the direction opposite to the fourth direction DR4, of the first emission part EP1b of the first emission parts EP1. In other words, the conductive pattern MP may be located adjacent to the longer side LS of the sides of the first emission part EP1, and may not be located adjacent to the shorter side SS of the first emission part EP1. The conductive pattern MP may block a portion of light which is output in the direction of the longer side LS and toward the transmissive part TP. Accordingly, a constant amount of light may be emitted from the first emission part EP1 at whole angles of direction, and the difference in brightness between angles of direction may be relatively reduced in the first emission part EP1 including the longer side LS and the shorter side SS. However, embodiments according to the present disclosure are not limited thereto.

Meanwhile, each of the second patterns MP2 may have a third length L3. According to some embodiments, one second pattern MP2 may extend to be adjacent to a side of the second emission part EP2 and a side of the third emission part EP3. In other words, the second pattern MP2 may extend to be adjacent to any one side of the sides of the second emission part EP2 and to any side of the sides of the third emission part EP3. Accordingly, the third length L3 may be at least the sum of a length of one side of the second emission part EP2 and a length of one side of the third emission part EP3. Accordingly, each of the second patterns MP2 may block light, which is output in the direction opposite to the fourth direction DR4 and leaks through the transmissive part TP, of light emitted from the second emission part EP2, and light which is output in the fourth direction DR4 and leaks to the first emission part EP1 adjacent, of light emitted from the third emission part EP3. Accordingly, light may be blocked from leaking through a wide range, thereby preventing or reducing degradation of light transmittance in the first region A1. Meanwhile, this is provided only for the illustrative purpose. The second pattern MP2 may have various lengths, and embodiments according to the present disclosure are not limited to any one embodiment.

Referring to FIG. 10, each of the first and second patterns MP1 and MP2 may be adjacent to only any one side of the sides of each of the second emission part EP2 and the third emission part EP3. However, the shape of the conductive pattern MP illustrated in FIG. 10 is provided only for the illustrative purpose. For example, the arrangement shape and the length of the conductive pattern MP may be variously formed without limitation to any one shape or any one length.

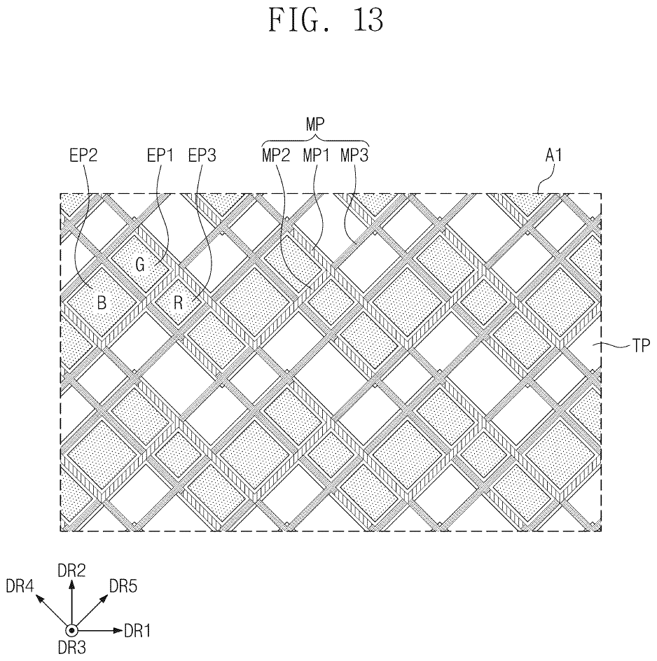

FIG. 12 is an enlarged plan view illustrating a partial region of an electronic apparatus. FIG. 12 illustrates an enlarged partial region of the first region A1 and an enlarged partial region of the second region A2 for the convenience of explanation. In addition, FIG. 12 illustrates the input sensor layer ISP together, when viewed from above the display surface IS (see FIG. 4) of the display module DM (see FIG. 4)

In the following description made with reference to FIG. 12, the same/similar reference numerals will be assigned to components the same/similar to components described with reference to FIGS. 8, 11A, and 11B and the redundant duplication will be omitted.

Referring to FIG. 12, the first and second patterns MP1 and MP2 may be adjacent to one side and an opposite side to the one side, which is different from FIG. 10. In other words, the conductive pattern MP may totally surround the second and third emission parts EP2 and EP3. For example, at least one of the first patterns MP1 may extend while being adjacent to a side, which faces the first emission part EP1 in the direction opposite to the fifth direction DR5, of the sides of the second emission part EP2 and a side which faces the transmissive part TP in the fifth direction DR5, of the sides of the third emission part EP3. Another one of the first patterns MP1 may extend while being adjacent to a side, which faces the first emission part EP1 in the fifth direction DR5, of the sides of the second emission part EP2, and a side which faces the transmissive part TP in the fifth direction DR5, of the sides of the third emission part EP3.

In addition, at least one of the second patterns MP2 may extend while being adjacent to a side, which faces the first emission part EP1 in the direction opposite to the fifth direction DR5, of the sides of the second emission part EP2 and a side which faces the transmissive part TP in the fifth direction DR5, of the sides of the third emission part EP3. Another one of the second patterns MP2 may extend while being adjacent to a side, which faces the first emission part EP1 in the fifth direction DR5, of the sides of the second emission part EP2, and a side which faces the transmissive part TP in the direction opposite to the fifth direction DR5, of the sides of the third emission part EP3.

Each of the first patterns MP1 and the second patterns MP2 may block light, which leaks from an adjacent emission part and the transmissive part TP, of light emitted from the second and third emission parts EP2 and EP3. Accordingly, a constant amount of light may be emitted from the second and third emission parts EP2 and EP3 at whole angles of direction, and the electronic apparatus having the uniform brightness value may be provided. In addition, as compared to when the conductive pattern MP is located adjacent to only any one side of sides of the second and third emission parts EP2 and EP3, the number of the conductive pattern MP may be increased, and the touch sensitivity may be relatively improved.

However, the shape of the conductive pattern MP illustrated in FIG. 12 is provided only for the illustrative purpose. For example, the arrangement shape and the length of the conductive pattern MP may be variously formed without limitation to any one shape or any one length.

FIG. 13 is an enlarged plan view illustrating a partial region of an electronic apparatus. FIG. 13 illustrates an enlarged partial region of the first region A1 and an enlarged partial region of the second region A2 for the convenience of explanation. In addition, FIG. 13 illustrates the input sensor layer ISP together, when viewed from above the display surface IS (see FIG. 4) of the display module DM (see FIG. 4).

In the following description made with reference to FIG. 13, the same/similar reference numerals will be assigned to components the same/similar to components described with reference to FIGS. 8 and 12 and the redundant duplication will be omitted.

Referring to FIG. 13, according to some embodiments, the conductive pattern MP may further include third patterns MP3 overlapped with the transmissive part TP. In this case, the third patterns MP3 may be located in a layer different from a layer for the first and second patterns MP1 and MP2. For example, the third patterns MP3 may be located under the first and second patterns MP1 and MP2.

The third patterns MP3 may be electrically connected to the first sensing electrodes TE1 (see FIG. 8) or the second sensing electrodes TE2 (see FIG. 8). As conductive patterns connected to the first and second sensing electrodes TE1 and TE2 are additionally located in the region overlapped with the transmissive part TP, the electronic apparatus relatively improved in touch sensitivity may be provided.

The third patterns MP3 may include a material different from a material for the first and second patterns MP1 and MP2. The third patterns MP3 may include a transparent conductive oxide TCO. For example, the third patterns MP3 may include indium tin oxide (ITO), indium zinc oxide (IZO), zinc oxide (ZnOx), or indium zinc tin oxide (IZTO). The third patterns MP3 overlapped with the transmissive part TP when viewed in a plan view may be provided in the form of a transparent pattern, thereby relatively improving the light transmittance on the transmissive part TP. Accordingly, the brightness and the transparence of the screen image may be relatively improved. In addition, camera performance may be optimized in the first region A1 including the transmissive part TP.

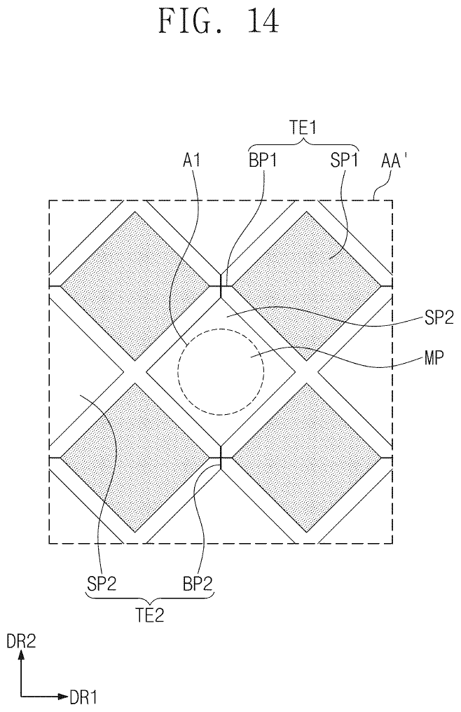

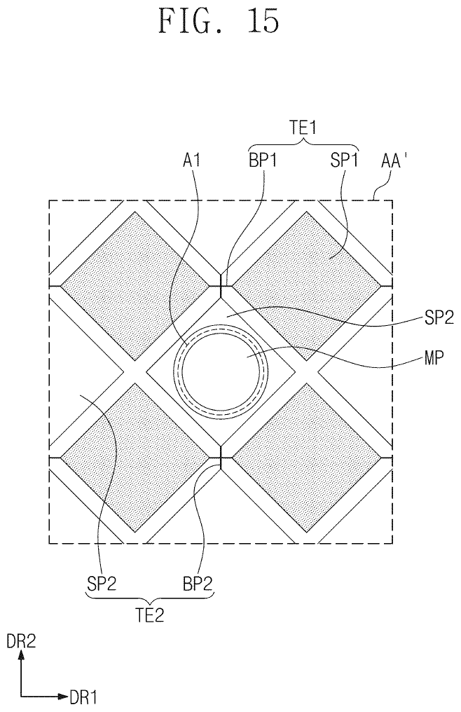

FIGS. 14 and 15 are enlarged plan views of region AA′ of FIG. 8. In the following description made with reference to FIGS. 14 to 15, the same/similar reference numerals will be assigned to components the same/similar to components described with reference to FIGS. 8 and 13 and the redundant duplication will be omitted.

Referring to FIG. 14, the first region A1 may be overlapped with only anyone electrode TE2 when viewed in a plan view. For example, the first region A1 may be overlapped with only anyone sensing pattern SP2. According to some embodiments, as illustrated in drawings, the first region A1 may be overlapped with the second sensing pattern SP2. The first region A1 may be overlapped with the second sensing electrode TE2, and may be in a non-overlap state with the first sensing electrode TE1. The first region A1 may have a circle shape, when viewed in a plan view, and the diameter of the circle may be at most 3.64 mm. The diameter of at most 3.64 mm may prevent or reduce a deterioration phenomenon such as reduction in resolution, and irregularity in pixel and color. However, this is provided only for the illustrative purpose. For example, various overlap shapes may be formed depending on the size of the first region A1 and the area of the sensor parts, and embodiments according to the present disclosure are not limited thereto.

The conductive pattern MP located in the first region A1 may be connected to the second sensing electrode TE2 to form a portion of the second sensing pattern SP2. Accordingly, the conductive pattern MP may perform a sensing function as a touch electrode, together with the first and second sensing electrodes TE1 and TE2 located in the second region A2, thereby preventing or reducing degradation of the touch sensitivity in the first region A1 and a region adjacent to the first region A1.

Meanwhile, referring to FIG. 15, the conductive pattern MP may be spaced apart from the first and second sensing electrodes TE1 and TE2 when viewed in a plan view. The conductive pattern MP may be electrically insulated from the first and second sensing electrodes TE1 and TE2. In other words, the conductive pattern MP may not be connected to the first and second sensing electrodes TE1 and TE2. In this case, as compared to when the conductive pattern MP is electrically connected to the first and second sensing electrodes TE1 and TE2, the manufacturing process may be simplified, and the manufacturing costs may be saved. In addition, as the conductive pattern MP does not exert an influence on the sensitivity of the first and second sensing electrodes TE1 and TE2, the conductive pattern MP may be designed in a smaller area or in various shapes to relatively improve transmittance, which relatively improves the degree of freedom in design.

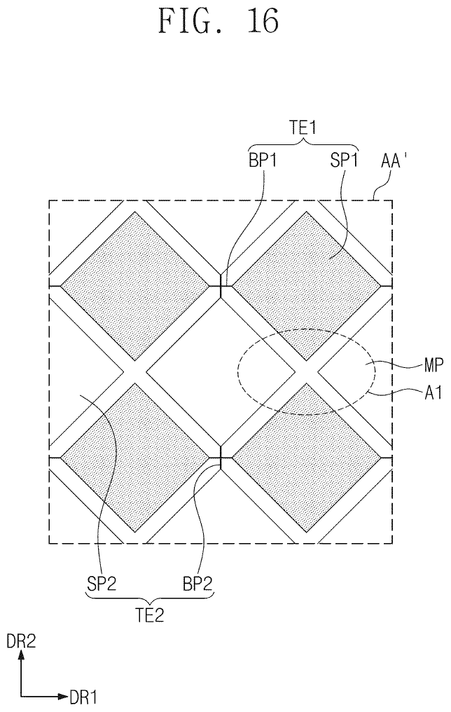

FIG. 16 are enlarged plan views of region AA′ of FIG. 8. In the following description made with reference to FIG. 16, the same/similar reference numerals will be assigned to components the same/similar to components described with reference to FIGS. 8 and 15 and the redundant duplication will be omitted.

Referring to FIG. 16, the first region A1 may have an elliptical shape when viewed in a plan view. The first region A1 may be overlapped with at least a portion of the first sensing electrode TE1 adjacent to the first region A1, and at least a portion of the second sensing electrodes TE2 adjacent to the first region A1, when viewed in a plan view. According to some embodiments, as illustrated in drawings, the first region A1 may be overlapped with a partial region of the two first sensing electrodes TE1 and a partial region of two second sensing electrodes TE2. The first region A1 having the elliptical shape may have an area larger than an area of the first region A1 having a circle shape illustrated in FIG. 12. For example, according to some embodiments, the length of the major axis of the ellipse may be at most 7.8 mm, and the length of the minor axis of the ellipse may be at most 4.5 mm. When the length of the major axis of the ellipse is at most 7.8 mm, and the length of the minor axis of the ellipse is at most 4.5 mm, a deterioration phenomenon such as reduction in resolution, and irregularity in pixel and color may be prevented or reduced.

The conductive pattern MP located in the first region A1 may be connected to the first sensing electrode TE1 and the second sensing electrode TE2 to form a portion of the first and second sensing patterns SP1 and SP2. Accordingly, the conductive pattern MP may perform a sensing function as a touch electrode, together with the first and second sensing electrodes TE1 and TE2 located in the second region A2, thereby preventing or reducing degradation of the touch sensitivity in the first region A1 and a region adjacent to the first region A1. In this case, as compared to when the conductive pattern MP is connected to only any one of the first and second sensing electrodes TE1 and TE2, the recognition precision for the change in capacitance between the first and second sensing electrodes TE1 and TE2 may be relatively improved. Accordingly, the touch sensitivity may be relatively improved.

As described above, according to the present disclosure, the green pixel may have the shape including a longer side and a shorter side having mutually different lengths. In this case, the conductive pattern may be located at a region adjacent to the longer side of the green pixel located in the UPC region, and may not be located at a region adjacent to the shorter side of the green pixel. Accordingly, the difference in an amount of light, which is varied depending on the phase, may be relatively reduced in vicinity of the green pixel, so the difference in brightness may be relatively reduced.

In addition, as the touch electrode is located in the UPC region, the electronic apparatus may be provided with relatively improved touch sensitivity.

Although aspects of some embodiments of the present disclosure have been described for illustrative purposes, those skilled in the art will appreciate that various modifications, and substitutions are possible, without departing from the scope and spirit of embodiments according to the present disclosure as disclosed in the accompanying claims, and their equivalents.

While aspects of some embodiments of the present disclosure have been described with reference to embodiments thereof, it will be apparent to those of ordinary skill in the art that various changes and modifications may be made thereto without departing from the spirit and scope of the present disclosure as set forth in the following claims, and their equivalents.

What is claimed is:

1. An electronic apparatus comprising:
a display panel divided into a display region including a first region and a second region, which has a transmittance lower than a transmittance of the first region, and a non-display region adjacent to the display region in a plan view; and
an input sensor layer on the display panel, and including a plurality of first sensing electrodes in the display region and extending in a first direction, a plurality of second sensing electrodes in the display region and extending in a second direction crossing the first direction, and a conductive pattern in the first region,
wherein the display panel includes:
a plurality of first emission parts, each of the first emission parts including a longer side extending in a first diagonal direction tilted with respect to the first direction and the second direction, and a shorter side extending in a second diagonal direction crossing the first diagonal direction;
a plurality of second emission parts, each of the second emission parts having sides having an equal length; and
a plurality of transmissive parts in the first region and spaced apart from the first and second emission parts,
wherein the conductive pattern includes:
a plurality of first patterns extending in the first diagonal direction and a plurality of second patterns extending in the second diagonal direction, and
wherein at least one of the first patterns is adjacent to the longer side among the longer sides that faces a transmissive part from among the transmissive parts.

2. The electronic apparatus of claim 1, wherein some of the first patterns have a length equal to a length of the longer side.

3. The electronic apparatus of claim 2, wherein the conductive pattern is electrically connected to the first sensing electrodes and electrically insulated from the second sensing electrodes.

4. The electronic apparatus of claim 2, wherein the conductive pattern is electrically insulated from the first sensing electrodes and the second sensing electrodes.

5. The electronic apparatus of claim 2, wherein the first patterns, which have the length equal to the length of the longer side, of the first patterns are adjacent to longer sides facing the transmissive part.

6. The electronic apparatus of claim 5, wherein the first patterns and the second patterns are adjacent to only one side of the sides of the second emission parts.

7. The electronic apparatus of claim 5, wherein the first patterns and the second patterns are adjacent to one side of the second emission parts and a side opposite to the one side.

8. The electronic apparatus of claim 6, further comprising:
third emission parts including sides having an equal length as a second length,
wherein the second emission parts are at the longer sides of the first emission parts, and the third emission parts are at the shorter sides of the first emission parts.

9. The electronic apparatus of claim 3, wherein the conductive pattern further includes:
third patterns overlapped with the plurality of transmissive parts.

10. The electronic apparatus of claim 9, wherein the third patterns are in a layer different from a layer for the first patterns and the second patterns.

11. The electronic apparatus of claim 10, wherein the third patterns include a material different from a material for the first patterns and the second patterns.

12. The electronic apparatus of claim 11, wherein the third patterns include a transparent conductive oxide.

13. The electronic apparatus of claim 12, wherein the third patterns are electrically connected to the first sensing electrodes or the second sensing electrodes.

14. The electronic apparatus of claim 1, wherein the first region has a circle shape in the plan view.

15. The electronic apparatus of claim 14, wherein the first region is overlapped with one of the first sensing electrodes and the second sensing electrodes, in the plan view.

16. The electronic apparatus of claim 2, wherein the first region has an elliptical shape in the plan view.

17. The electronic apparatus of claim 16, wherein the first region is overlapped with at least a portion of the first sensing electrodes and at least a portion of the second sensing electrodes that are adjacent to the first region in the plan view.

18. The electronic apparatus of claim 17, wherein the conductive pattern is electrically connected to the first and second sensing electrodes.

19. An electronic apparatus comprising:
a camera module;
a display panel divided into a display region, which includes a first region overlapped with the camera module and a second region having a transmittance lower than a transmittance of the first region, and a non-display region adjacent to the display region, in a plan view; and
an input sensor layer on the display panel, and including a plurality of first sensing electrodes in the display region and extending in a first direction, a plurality of second sensing electrodes in the display region and extending in a second direction crossing the first direction, and a conductive pattern in the first region,
wherein the display panel includes:
a plurality of first emission parts, each of the first emission parts including a longer side extending in a first diagonal direction tilted with respect to the first direction and the second direction, and a shorter side extending in a second diagonal direction crossing the first diagonal direction;
a plurality of second emission parts, each of the second emission parts having sides having an equal length; and
a plurality of transmissive parts in the first region and spaced apart from the first and second emission parts,
wherein the conductive pattern includes:
a plurality of first patterns extending in the first diagonal direction and a plurality of second patterns extending in the second diagonal direction, and
wherein at least one of the first patterns is adjacent to the longer side among the longer sides that faces a transmissive part from among the transmissive parts.

20. The electronic apparatus of claim 19, wherein some of the first patterns have a length equal to a length of the longer side, and first patterns, which have the length equal to the length of the longer side, of the first patterns are adjacent to longer sides facing the transmissive part.
